(19) United States
(12) Patent Application Publication
(10) Pub. No.: US 2008/0079124 A1
(43) Pub. Date: Apr. 3, 2008

(54) INTERDIGITATED LEADFINGERS

(76) Inventors: CHRIS EDWARD HAGA, McKinney, TX (US); WILLIAM DAVID BOYD, Frisco, TX (US); ANTHONY LOUIS COYLE, Plano, TX (US)

Correspondence Address: TEXAS INSTRUMENTS INCORPORATED, P O BOX 655474, M/S 3999, DALLAS, TX, 75265, US

(21) Appl. No.: 11/734,479

(22) Filed: Apr. 12, 2007

Related U.S. Application Data
(60) Provisional application No. 60/827,998, filed on Oct. 3, 2006.

(51) Int. Cl. H01L 23/495; H01L 21/00

(52) U.S. Cl. 257/666; 438/123; 257/E23.031; 257/E21.001

(57) ABSTRACT

One embodiment of the present Invention includes an integrated circuit (IC) package. The IC package comprises a semiconductor die comprising at least one IC. The semiconductor die can include a plurality of conductive elements disposed on a first surface of the semiconductor die. The IC package also comprises a die pad coupled to a second surface of the semiconductor die. The IC package further comprises a leadframe comprising a plurality of leadfingers to which a portion of the conductive elements are conductively coupled. At least a portion of the plurality of leadfingers can be interdigitated with at least a portion of the die pad.

### RELATED APPLICATION

This application claims the benefit of U.S. Provisional Patent Application No. 60/827,998 which was filed on Oct. 3, 2006, and entitled “Interdigitated QFN Leadframe,” which is incorporated herein by reference.

### TECHNICAL FIELD

This invention relates to integrated circuit (IC) packaging, and more specifically to interdigitated leadfingers.

### BACKGROUND

In a given integrated circuit (IC) package, bond wires may be employed to couple the inputs and outputs of the semiconductor die, which includes the IC, to other parts of the IC package. For example, the semiconductor die may be adhesively bonded to a die pad, such that bond wires can conductively couple the IC package to the die pad to provide a ground connection for the IC. As another example, the IC package may include a leadframe with a plurality of leadfingers, with each of the leadfingers being coupled to I/O pins configured external to the IC package. Therefore, bond wires can also be used to couple power and signal conductive contacts of the semiconductor die to the leadfingers corresponding to respective power and signal I/O pins of the IC package.

Certain types of IC packages have specific configurations for bond wires. For example, in a Quad Flat package with No leads (QFN) type of IC package, the conductive contacts of the semiconductor die can be located on a top surface of the semiconductor die opposite the surface that is adhesively mounted to the die pad, and the leadfingers can be coplanar with the die pad. As a result, the bond wires used to make the electrical connections to the die pad via down bonds and to the leadfingers via leadfinger bonds extend from the top surface of the semiconductor die and are bent to make contact with a surface plane that is below the top surface of the semiconductor die. Therefore, the bond wires are coupled to the down bonds and the leadfinger bonds are arched from the top surface of the semiconductor die to make electrical contact with either the die pad or the leadfingers, respectively, below the top surface of the semiconductor die.

Manufacturing constraints may dictate minimum lengths and/or specific configurations of the bond wires that make the electrical connections from the semiconductor die to other portions of the IC package. In the example of a QFN package, the bond wires can be made of gold or copper, and can thus be limited in the amount of bending that can be applied to the bond wire before the bond wire breaks. In addition, the adhesive that bonds the semiconductor die to the die pad may “bleed-out”, thus seeping-out and collecting along the perimeter of the semiconductor die at the bond to the die pad. Therefore, due to the amount of bleed-out of the adhesive material and/or the limitations of bending of the bond wires, a minimum distance from an edge of the semiconductor die to a down bond can be required in certain applications.

In addition, there may be a required minimum distance from a down bond or a leadfinger bond to an edge of the die pad or an edge of a leadfinger, respectively. Thus, as an example, the minimum distance from the edge of the semiconductor die to the adjacent edge of the die pad can be approximately 2.5 mils. Furthermore, the IC package may have a minimum required amount of etching distance between the leadfingers of the leadframe and the die pad. Accordingly, due to the minimum spacing of the edge of the semiconductor die to the edge of the die pad and the minimum spacing of the leadfingers from the die pad, as well as the minimum distance of a leadfinger bond to a leadfinger edge, a minimum spacing from the edge of the semiconductor die to the leadfinger bonds can he required. For some IC applications, such as an IC that is implemented in a communication device, such a lateral connection distance can result in an undesirable amount of inductance for critical high-frequency leads.

### SUMMARY

One embodiment of the present invention includes an integrated circuit (IC) package. The IC package comprises a semiconductor die comprising at least one IC. The semiconductor die can include a plurality of conductive elements disposed on a first surface of the semiconductor die. The IC package also comprises a die pad coupled to a second surface of the semiconductor die. The IC package former comprises a leadframe comprising a plurality of leadfingers to which a portion of the conductive elements are conductively coupled. At least a portion of the plurality of leadfingers can be interdigitated with at least a portion of the die pad.

Another embodiment of the present invention includes an IC package. The IC package comprises a semiconductor die comprising at least one IC and a die pad having a bonding surface on which a first surface of the semiconductor die is attached. The die pad can comprise at least one projection extending from a first substantially rectangular perimeter of the die pad to terminate in a distal end thereof that defines at least one side of a second substantially rectangular perimeter. A leadframe has a surface that is arranged substantially coplanar with the bonding surface of the die pad, die leadframe extending along at least one side of the second substantially rectangular perimeter, at least a portion of the leadframe extending Into the at least one side of the second substantially rectangular.

Another embodiment of the present invention includes a method for fabricating an IC package. The method comprises partially etching a portion of a metal layer to define a die pad and a leadframe. The method also comprises etching through the partially etched portion of the metal layer to define a plurality of leadfingers coupled to the leadframe and at least one projection extending from the die pad. The plurality of leadfingers can be interdigitated with the at least one projection. The method also comprises attaching a semiconductor die to the die pad and coupling a portion of a plurality of conductive surfaces of the semiconductor die to the die pad. The method further comprises electrically coupling a remainder of the plurality of conductive surfaces of the semiconductor die to respective ones of the plurality of leadfingers.

### BRIEF DESCRIPTION OF HIE DRAWINGS

FIG. 1 illustrates an example of a portion of an integrated circuit (IC) package in accordance with an aspect of the invention.

FIG. 2 illustrates an example of a cross-sectional view of the portion of the IC package of FIG. 1 In accordance with an aspect of the invention.

FIG. 3 illustrates another example of a cross-sectional view of the portion of the IC package of FIG. 1 in accordance with an aspect of the invention.

FIG. 4 illustrates an example of an IC package in accordance with an aspect of the invention.

FIG. 5 illustrates an example of a method for fabricating an IC package in accordance with an aspect of the invention.

### DETAILED DESCRIPTION

The present invention relates generally to integrated circuit (IC) packaging, and more specifically to an Interdigitated leadframe. The leadfingers of the leadframe of an IC package can he configured such that they are interdigitated with the die pad. Specifically, the die pad can include at least one projection from a first substantially rectangular perimeter to define a second substantially rectangular perimeter. The leadfingers of the leadframe can thus be interdigitated with the at least one projection of the die pad, such mat the leadfingers that substantially surround the die pad extend into the second substantially rectangular perimeter. As a result, a lateral connection distance of the bond wires from the edge of the semiconductor die that is adhesively mounted on the die pad to the leadfinger bonds can be substantially reduced, such as from approximately 40 mils to approximately 20 mils. Therefore, an amount of inductance on critical high-frequency leads associated with the IC can be substantially reduced.

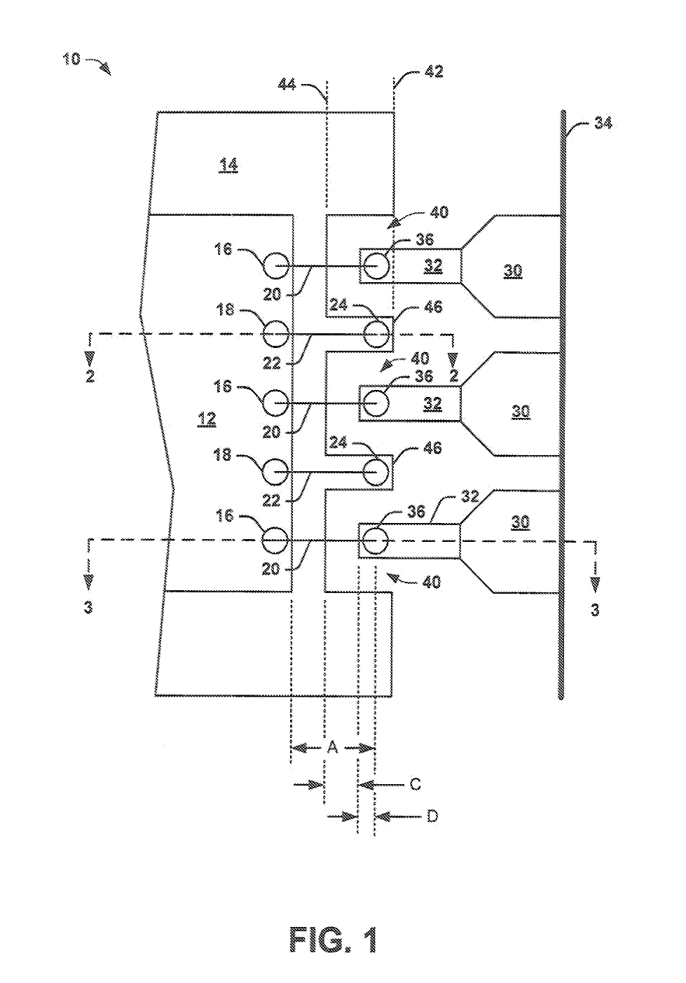

FIG. 1 illustrates an example of a portion of as IC package 10 in accordance with an aspect of fee invention. The IC package 10 is demonstrated in the example of FIG. 1 from an overhead view, and could be a Quad Flat package with No leads (QFN) type of IC package. The IC package 10 includes a semiconductor die 12 that is adhesively mounted on a die pad 14. The semiconductor die 12 can include one or more ICs configured to perform any of a variety of functions. The semiconductor die 12 includes a plurality of conductive elements 16 and 18 disposed on a top surface of the semiconductor die 12. The conductive elements 16 can include contacts for power, inputs, and/or outputs. The conductive elements 18 can include contacts for ground. Each of the conductive elements 16 and 18 is configured to be coupled to bond wires 20 and bond wires 22, respectively. As an example, the bond wires 20 and 22 can be electrically coupled to the respective one of the conductive elements 16 and 18 via a solder bump.

The bond wires 22 interconnect the conductive elements 18 with a down bond 24 on the die pad 14, such as via a solder bump. As an example, the die pad 14 can be coupled to ground at the bottom (not shown) of the IC package 10, such that the down bonds 24 can provide ground connections for the one or more ICs that are included in the semiconductor die 12 via the bond wires 22.

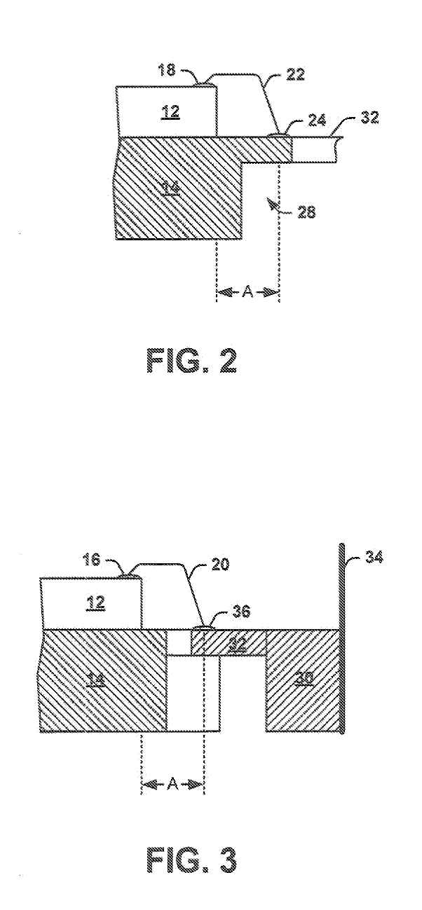

FIG. 2 illustrates an example of a partial cross-sectional view of the portion of the IC package 10 of the example of FIG. 1, taken along line indicated at 2-2. The example of FIG. 2 demonstrates the semiconductor die 12 in an orientation on a top surface of the die pad 14. For example, the semiconductor die 12 can be attached to the die pad 14, such as by an adhesive or other attachment mechanism. The die pad 14 includes a half-etched portion 28, such as could result from an etching process that is implemented to fabricate the IC package 10. In addition, the example of FIG. 2 demonstrates the bond wire 22 being bent to conductively couple the conductive element 18 at the top of the semiconductor die to the down bond 24 on a lower planar surface on the die pad 14.

An amount of lateral connection distance between the edge of the semiconductor die 12 and the down bond 24 is demonstrated in the example of FIGS. 1 and 2 as “A”. The lateral connection distance “A” can be subject to manufacturing constraints. The manufacturing constraints can dictate minimum lengths and/or specific configurations of the bond wires 22 that make the electrical connections from the semiconductor die 12 to the IC package 10. For example, the bond wires 22 can be formed from gold or copper, and can thus be limited in the amount of bending that can be applied before the bond wires 22 break. Specifically, as the lateral connection distance “A” decreases, the bond wires are subject to increased bending, thus increasing the likelihood of breaking. In addition, the adhesive that that attaches the semiconductor die 12 to the die pad 14 may “bleed-out”, thus seeping-out and collecting along the perimeter of the semiconductor die 12 at the bond to the die pad 14. The amount of bleed-out of the adhesive material and/or the limitations of bending of the bond wires 22 can impose a minimum lateral connection distance “A”, which in a given application, for example, can be approximately 20 mils.

Referring back to FIG. 1, the IC package 10 includes a leadframe 30 that includes a plurality of leadfingers 32. The leadframe 30 can be coupled to one or more walls of the IC package 10, demonstrated as the solid line 34 in the example of FIG. 1. The leadfingers 32 can each be coupled to a respective one of a plurality of I/O pins (not shown) on the exterior of the IC package 10. The leadframe 30 can be configured to electrically isolate the leadfingers 32 from each other, and/or can provide conductive coupling between one or more of the leadfingers 32. The bond wires 20 interconnect the conductive elements 16 with a leadfinger bond 36 on each of the leadfingers 32, such as may be provided a solder bump. As an example, each of the leadfingers 32 can correspond to or be electrically connected to power, input signal, and/or output signal pins on the exterior of the IC package 10.

FIG. 3 illustrates an example of a cross-sectional view of the portion of the IC package 10 of the example of FIG. 1, taken along the line indicated at 3-3. The-example of FIG. 3 demonstrates the semiconductor die 12 on top of the die pad 14 (e.g., the semiconductor die 12 can be adhesively coupled to the die pad 14). The leadfinger 32 demonstrated in the example of FIG. 3 may be a half-etched portion of the leadframe 30, such as could result from an etching process that is implemented to fabricate the IC package 10. In addition, the example of FIG. 3 demonstrates that a surface of the leadfinger 32 is coplanar with a corresponding surface of the die pad 14 to which the die is attached. The bond wire 20 can be bent to electrically couple the conductive element 16 at the top of the semiconductor die 12 to a corresponding leadfinger bond 36, similar to the down bond 24 coupling demonstrated In the example of FIG. 2.

Referring back to the example of FIG. 1, manufacturing constraints may dictate a minimum required amount of etching distance between the leadfingers 32 of the leadframe 30 and the die pad 14, demonstrated in the example of FIG. 1 as a distance “C”. In addition, manufacturing constraints may also dictate a minimum distance between a leadfinger bond 36 and an edge of a leadfinger 32, demonstrated in the example of FIG. 1 as a distance “D”. In a typical IC package, these minimum distances, as well as a minimum lateral connection distance from a semiconductor die to a down bond, can result in a minimum lateral connection distance of the edge of the semiconductor die to a given leadfinger bond (e.g., for certain applications of approximately 40 mils), such as approximately twice the minimum lateral connection distance “A”. For certain applications, such as an IC that Is implemented in a communication device, such an increased lateral connection distance can require a corresponding length bond which can result in an undesirable amount of inductance (e.g., high-frequency signal leads).

In the IC package 10 in the example of FIG. 1, the die pad 14 is etched, such as at the partially etched region 28, to Include a plurality of recesses 40 arranged substantially adjacent to each of the down bonds 24. Specifically, the die pad 14 is recessed from a first edge demonstrated by the dashed line 42, to a second edge, demonstrated by the dashed line 44. Therefore, the recesses 40 can define a plurality of projections 46 that each extend laterally outwardly from the second edge 44 of the die pad 14 to the first edge 42 of the die pad 14. Each of the down bonds 24 is respectively located on each of the respective projections 46 of the die pad 14. In a the example of FIG. 1, each of the leadfingers 32 extends into a respective one of the recesses 40, such that a distal end portion the leadfingers 32 extend beyond the boundary defined by the first edge 42. Accordingly, the leadfingers 32 are interdigitated with the projections 46. Additionally, the lead finger bonds 36 can be aligned in a substantially linear arrangement with corresponding down bonds 24 within the respective recesses 40 (e.g., located within the edge 42 of the die pad 14).

As a result of the interdigitation of the leadfingers 32 with the projections 46, the leadfinger bonds 36 can be located closer to the edge of the semiconductor die 12 without violating a required minimum lateral connection distance “A” of the edge of fee semiconductor die 12 to each of the down bonds 24. Specifically, as demonstrated in the example of FIGS. 1 and 3, the leadfingers 32 can be arranged such that the lateral connection distance of the edge of the semiconductor die 12 to each of the leadfinger bonds 36 can be “A”. Therefore, the lateral connection distances of the edge of the semiconductor die 12 to each of the down bonds 24 and of the edge of the semiconductor die 12 to each of the leadfinger bonds 36 can be approximately equal (e.g., “A”=20 mils). Accordingly, inductance associated with signal connections from the conductive elements 16 to the leadfinger bonds 36 via the bond wires 20 can be substantially reduced.

It is to be understood that the IC package 10 is not intended to be limited to the examples of FIGS. 1-3. For example, in the example of FIG. 1, the interdigitation of the leadfingers 32 and the projections 46 may not be on a one-for-one basis, as depicted in the example of FIG. 1. Alternatively, the interdigitation can include multiple leadfingers 32 interposed between a pair of adjacent die pad projections 46 that include down bonds 24. As yet another example, a single projection 46 that includes a down bond 24 could be interposed between as to separate two adjacent sets of multiple leadfingers 32. Each of the leadfingers 32 and/or projections 46 are not limited to including on a single leadfinger bond 36 and/or down bond 24, respectively, but could each have none or more than one. Those skilled in the art will understand and appreciate various arrangements of interdigitation between leadfingers and die pad projections that can be implemented according to an aspect of the invention.

In addition, although the example of FIG. 1 demonstrates interdigitation on only one side of the semiconductor die 12, it is to be understood that the leadframe 30 could occur on any number of one or more sides of the die pad 14. As an example, the lead frame 30 can substantially surround the semiconductor die 12 and die pad 14, such that interdigitation of leadfingers 32 with projections 46 that include down bonds 24 could occur on up to all four of the sides of the semiconductor die 12. Additionally, the lateral connection distance from the edge of the semiconductor die 12 to the leadfinger bonds 36 may not necessarily be substantially equal to the lateral connection distance “A”, but could be slightly more or even slightly less than the lateral connection distance “A”, such that the leadfinger bonds 36 may not be substantially equal to the lateral connection distance of the down bonds 24. As an example, the lateral connection distance of the leadfinger bonds 36 could be less than 25 mils. Furthermore, it is to be understood that the projections 46 may not define recesses 40, such as in an example of an IC package 10 that includes no more than one projection 46 on any one side. Therefore, the IC package 10 can be configured in any of a variety of different ways in the example of FIGS. 1-3.

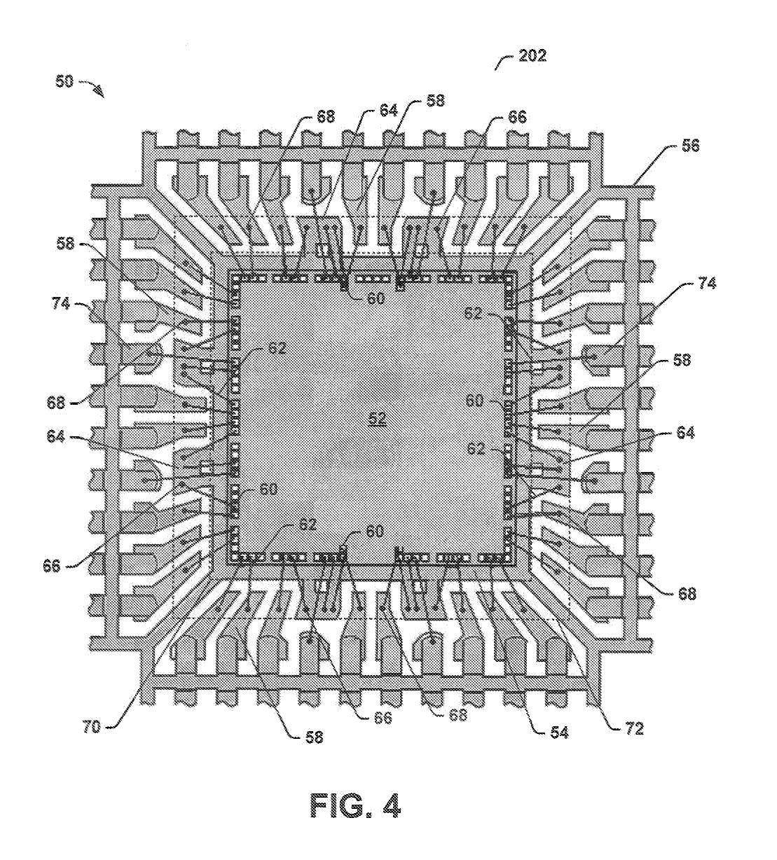

FIG. 4 illustrates one example of an IC package 50 in accordance with an aspect of the invention. The IC package 50 is demonstrated in the example of FIG. 4 from an overhead view, and could be a QFN type of IC package. The IC package 50 includes a semiconductor die 52 that is mounted on a die pad 54. The semiconductor die 52 can include one or more ICs configured to perform any of a variety of functions. The IC package 50 also includes a leadframe 56 that includes a plurality of leadfingers 58. The leadfingers 58 can each be coupled to a respective one of a plurality of I/O pins (not shown) on the exterior of the IC package 50. In the example of FIG. 4, the die pad 54 and the leadframe 56 are coupled together. It is to be understood that the IC package 50 in the example of FIG. 4 is not limited to such an arrangement, in that the die pad 54 and the leadframe 56 can be configured separate from each other.

The semiconductor die 52 includes a plurality of conductive elements 60 disposed on a top surface of the semiconductor die 52. The conductive elements 60 can include contacts for power, ground, inputs, aid/or outputs. The conductive elements 60 are coupled to one of a leadfinger 58 or to the die pad 54, respectively, via a bond wire 62. Thus, the conductive elements 60 can be coupled to a down bond 66 of the die pad 54 or to a leadfinger bond 68. In the example of FIG. 4, the die pad 54 includes projections 64 that include the down bonds 66. The projections 64 extend from a first substantially rectangular perimeter 70 of the die pad 54 and define a second substantially rectangular perimeter 72 of the die pad 54. In the example of FIG. 4, the down bonds 66 can be separated from the semiconductor die 52 by a substantially minimum lateral connection distance (e.g., 20 mils), such as may be dictated by manufacturing constraints.

In the example of FIG. 4, the leadfingers 58 are formed (e.g., by etching) such that they extend into the second substantially rectangular perimeter 72. As a result, the leadfingers 58 are interdigitated with the projections 64. Specifically, as demonstrated in the example of FIG. 4, the leadfingers 58 are arranged such that the lateral connection distance of the edge of the semiconductor die 52 to each of the leadfinger bonds 68 can be approximately equal to the lateral connection distance of the edge of the semiconductor die 52 to the down bonds 66. Accordingly, inductance associated with signal connections from the conductive elements 16 to the leadfinger bonds 36 via the bond wires 20 can be substantially reduced relative to many existing approaches.

It is to be understood that, in the example of FIG. 4, the interdigitation between the leadfingers 58 and the projections 64 are not on a one-to-one basis, such as demonstrated in the example of FIG. 1 above. Specifically, there are multiple adjacent leadfingers 58 laterally spaced between adjacent pairs of the projections 64. Furthermore, the leadframe 56 includes some leadfingers 74 that do not extend Into the second substantially rectangular perimeter 72, such that they are not interdigitated with the projections 64. The leadfingers 74 include leadfinger bonds 68, such as those that may not be sensitive to a length of a bond wire 62 with respect to inductance (e.g., power). That is, not all of the leadfingers of the leadframe 56 need to be interdigitated with the projections 64, as indicated by the leadfingers 74.

It is to be understood that the IC package 50 is not intended to be limited to the example of FIG. 4. For example, the IC package 50 is demonstrated in the example of FIG. 4 as being symmetrical about any 45° axis passing through the center of the semiconductor die 52. However, the symmetry of the IC package 50 is demonstrated by way of example, such that the IC package 50 may be different on any of the four sides relative to each other, including the etching of the leadfingers 58 and the projections 64. Those skilled in the art will understand and appreciated that the IC package 50 can be configured in any of a variety of different ways.

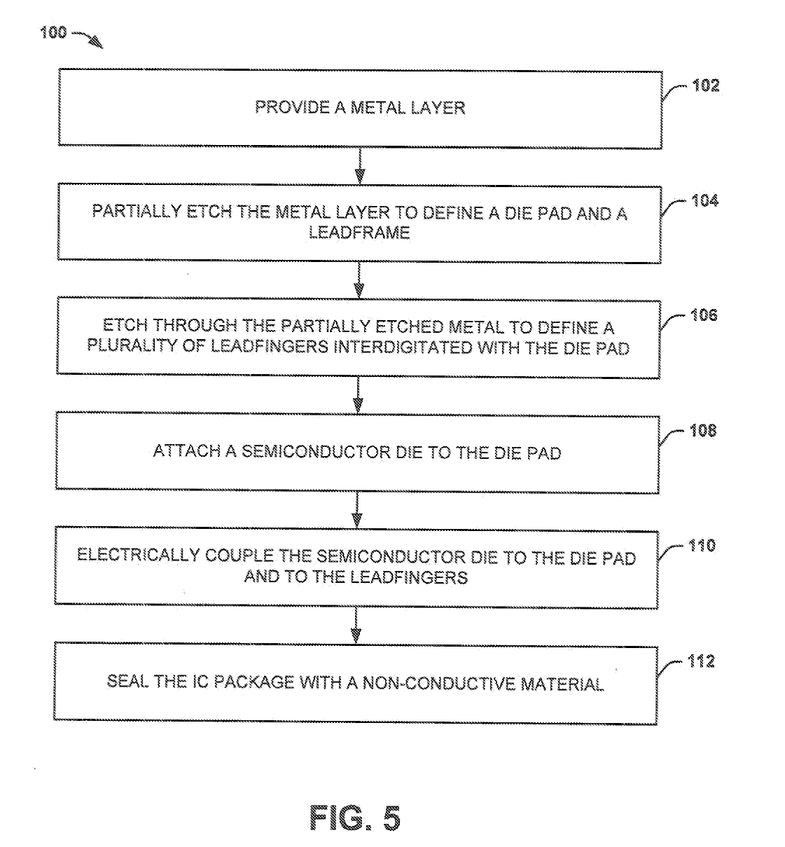

In view of the foregoing structural and functional features described above, certain methods will be better appreciated with reference to FIG. 5. It is to be understood and appreciated that the illustrated actions, in other embodiments, may occur in different orders and/or concurrently with other actions. Moreover, not all illustrated features may be required to implement a method.

FIG. 5 Illustrates a method 100 for fabricating an IC package. At 102, a metal layer is provided. At 104, the metal layer is partially etched to define a die pad and a leadframe. The die pad could be a metal surface upon which a semiconductor die is adhered, such that the die pad can provide a ground connection for one or more ICs within the semiconductor die. At 106, the partially etched metal is etched through to define leadfingers that are interdigitated with corresponding portions of the die pad. The leadfingers could be interdigitated with one or more projections extending from a substantially rectangular perimeter of the die pad. The leadfingers could be interdigitated such that multiple leadfingers are arranged between each pair of the projections. The leadfingers could be configured to provide a conductive coupling to I/O pins external to the IC package.

At 108, a semiconductor die is attached to the die pad (e.g., by adhesive or other bonding means). The adhesive employed to attach the semiconductor die to the die pad could result in bleed-out of adhesive material onto the surface of the die pad. Such bleed-out may require a minimum distance for spacing down bonds of bond wires from the edge of the semiconductor die to the die pad. At 110, bond wires are provided to conductively couple the semiconductor die to the die pad and to the leadfingers. The lateral connection distance of the down bonds and the leadfinger bonds from the semiconductor die can be approximately the same, or the leadfinger bonds can have a lateral connection distance that is less than the down bonds, due to the interdigitation of the leadfingers with the projections of the die pad. At 112, the IC package can be encapsulated, such as by sealing with a non-conductive material as is known in the art.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. An integrated circuit (IC) package comprising:
a semiconductor die comprising at least one IC, the semiconductor die including a plurality of conductive elements disposed on a first surface of the semiconductor die;
a die pad attached to a second surface of the semiconductor die; and
a leadframe comprising a plurality of leadfingers to which a portion of the conductive elements are conductively coupled, at least a portion of the plurality of leadfingers being interdigitated with at least a portion of the die pad.

2. The IC package of claim 1, wherein a surface of the plurality of leadfingers to which the portion of the plurality of conductive elements are coupled and a surface of the die pad to which the semiconductor die is coupled are configured substantially coplanarly relative to each other.

3. The IC package of claim 1, further comprising a plurality of bond wires configured to conductively couple each of the plurality of conductive elements with one of the die pad and a respective one of the plurality of leadfingers.

4. The IC package of claim 3, wherein at least one of the plurality of bond wires configured to conductively couple a respective at least one of the plurality of conductive elements with a respective at least one of the plurality of leadfingers has a length that is substantially equal to a length associated with at least one of the plurality of bond wires configured to conductively couple a respective at least one of the plurality of conductive elements with the die pad.

5. The IC package of claim 3, wherein at least one of the plurality of bond wires configured to conductively couple a respective at least one of the plurality of conductive elements with a respective at least one of the plurality of leadfingers has a lateral connection distance between an edge of the semiconductor die and a coupling to the respective at least one of the plurality of leadfingers that is less than or equal to approximately 25 mils.

6. The IC package of claim 3, wherein at least one of the plurality of bond wires is configured to conductively couple a respective at least one of the plurality of conductive elements on at least one projection associated with the die pad, and wherein at least a portion of the plurality of leadfingers are interdigitated with the at least one projection associated with the die pad.

7. The IC package of claim 1, wherein at least a portion of the plurality of leadfingers extend Into at least one recess associated with a perimeter of the die pad.

8. The IC package of claim 1, wherein the IC package is a Quad Flat package No leads (QFN).

9. An Integrated circuit (IC) package comprising;
a semiconductor die comprising at least one IC;
a die pad having a bonding surface on which a first surface of the semiconductor die is positioned, the die pad comprising at least one projection extending from a first substantially rectangular perimeter portion of the die pad to terminate in a distal end thereof that defines at least one side of a second substantially rectangular perimeter; and
a leadframe having a surface that Is arranged substantially coplanar with the bonding surface of the die pad, the leadframe extending along at least one side of the second substantially rectangular perimeter, at least a portion of the leadframe extending into the at least one side of the second substantially rectangular perimeter.

10. The IC package of claim 9, wherein the leadframe comprises a plurality of leadfingers interdigitated with the at least one projection of the die pad along the at least one side thereof.

11. The IC package of claim 10, further comprising a plurality of bond wires configured to conductively couple each of a plurality of conductive elements disposed on a second surface of the semiconductor die opposite the first surface with one of the die pad and a respective one of the plurality of leadfingers.

12. The IC package of claim 11, wherein at least one of the plurality of bond wires configured to conductively couple a respective at least one of the plurality of conductive elements with a respective at least one of the plurality of leadfingers has a lateral connection distance between an edge of the semiconductor die and a coupling to the respective at least one of the plurality of leadfingers that is less than or equal to approximately 25 mils.

13. The IC package of claim 9, wherein the at least one projection comprises a plurality of projections that extend laterally outwardly from at least two sides of the first substantially rectangular perimeter portion to terminate in distal ends of the plurality of projections, and
wherein the at least a portion of the leadframe comprises a plurality of lead fingers that extend laterally from the leadframe to terminate in distal ends residing with recesses defined between adjacent pairs of the plurality of projections along the at least two sides of the first rectangular perimeter portion of the die pad.

14. The IC package of claim 9, wherein the IC package is a Quad Flat package No leads (QFN).

15. A method for fabricating au Integrated circuit (IC) package, the method comprising:
partially etching a portion of a metal layer to define a die pad and a leadframe;
etching through the partially etched portion of the metal layer to define a plurality of leadfingers coupled to the leadframe and at least one projection extending from the die pad, the plurality of leadfingers being interdigitated with the at least one projection;
attaching a semiconductor die to the die pad;
electrically coupling a portion of a plurality of conductive surfaces of the semiconductor die to the die pad; and
electrically coupling a remainder of the plurality of conductive surfaces of the semiconductor die to respective ones of the plurality of leadfingers.

16. The method of claim 15, wherein coupling the portion of the plurality of conductive surfaces and coupling the remainder of the plurality of conductive surfaces comprises coupling the portion of the plurality of conductive surfaces and the remainder of the plurality of conductive surfaces to the respective die pad and the plurality of leadfingers via bond wires.

17. The method of claim 15, wherein the etching further comprises etchting through the metal layer to form the plurality of leadfingers interdigitated with a plurality of projections that extend laterally outwardly from at least two sides of the die pad, a distal edge of the plurality of leadfingers being spaced laterally apart from an inner perimeter edge of the die pad between adjacent pairs of the plurality of projections.

18. The method of claim 15, wherein coupling the portion of the plurality of conductive surfaces comprises coupling the portion of the plurality of conductive surfaces of the semiconductor die to the die pad at a plurality of down bonds, and wherein coupling the remainder of the plurality of conductive surfaces comprises coupling the remainder of the plurality of conductive surfaces of the semiconductor die to respective ones of the plurality of leadfingers at a lateral connection distance that is approximately equal to a lateral connection distance associated with the plurality of down bonds.

19. The method of claim 15, wherein the IC package is a Quad Flat package No leads (QFN).

20. An integrated circuit fabricated according to the method of claim 15.
